(19) United States
(12) Patent Application Publication
(10) Pub. No.: US 2026/0090196 A1
(43) Pub. Date: Mar. 26, 2026

(54) FILM, PREPARATION METHOD THEREOF AND PHOTOELECTRIC DEVICE

(71) Applicant: Shenzhen TCL High-Tech Development Co., Ltd., Shenzhen (CN)

(72) Inventor: Congcong CAO, Shenzhen (CN)

(73) Assignee: Shenzhen TCL High-Tech Development Co., Ltd., Shenzhen (CN)

(21) Appl. No.: 19/223,063

(22) Filed: May 30, 2025

(30) Foreign Application Priority Data
May 30, 2024 (CN) 202410698897.3

(51) Int. Cl. H10K 50/15; H10K 50/115; H10K 50/155; H10K 50/16; H10K 50/17; H10K 85/10; H10K 85/60

(52) U.S. Cl. CPC H10K 50/156; H10K 50/115; H10K 50/155; H10K 85/111; H10K 85/622; H10K 50/16; H10K 50/171

(57) ABSTRACT

A film, preparation method thereof and photoelectric device are disclosed. A material of the film includes an organic p-type semiconductor material and a dopant, and the dopant is selected from one or more of a polycyano conjugated compound and a polytrifluoromethyl conjugated compound. The film has high hole mobility.

This application claims priority to Chinese Application No. 202410698897.3, entitled “FILM, PREPARATION METHOD THEREOF, PHOTOELECTRIC DEVICE AND DISPLAY DEVICE”, filed on May 30, 2024. The entire disclosures of the above application are incorporated herein by reference.

### TECHNICAL FIELD

The present disclosure relates to a field of display technologies, and more particularly, to film, preparation method thereof and photoelectric device.

### BACKGROUND

In the related art, organic semiconductor material is an organic material whose conductivity is between metal and insulator, and it is usually used as the material of film. However, the carrier mobility of film prepared from organic semiconductor material is low, which needs to be further improved.

### Technical Solution

In view of this, the present disclosure provides a film, a preparation method thereof and a photoelectric device.

The present disclosure provides a film. A material of the film includes an organic p-type semiconductor material and a dopant, and the dopant is selected from one or more of a polycyano conjugated compound and a polytrifluoromethyl conjugated compound.

The present disclosure provides a preparation method of a film, including: providing a prefabricated film layer, and a material of the prefabricated film layer includes a first organic p-type semiconductor material; and providing a first material, setting the first material on the prefabricated film layer to form a first doped layer, and treating with organic solvent vapor to obtain the film: wherein the first material includes a dopant, and the dopant is selected from one or more of a polycyano conjugated compound and a polytrifluoromethyl conjugated compound.

The present disclosure provides a photoelectric device, including: an anode; an active layer, located on the anode; a cathode, located on the active layer; and a hole functional layer, between the anode and the active layer, and a material of the film includes an organic p-type semiconductor material and a dopant, and the dopant is selected from one or more of a polycyano conjugated compound and a polytrifluoromethyl conjugated compound.

The film provided by the present disclosure has high hole mobility.

### BRIEF DESCRIPTION OF DRAWINGS

In order to more clearly explain the technical solutions in the embodiments of the present disclosure, the following will briefly introduce the drawings required in the description of the embodiments. Obviously, the drawings in the following description are only some embodiments of the present disclosure. For those skilled in the art, without paying any creative work, other drawings could be obtained based on these drawings.

FIG. 1 is a flowchart of a method for preparing a film according to an embodiment of the present disclosure.

FIG. 2 is a schematic diagram of the structure of forming a first doped layer on a prefabricated film layer according to an embodiment of the present disclosure.

FIG. 3 is a schematic diagram of the structure of a film according to an embodiment of the present disclosure.

FIG. 4 is a schematic diagram of the structure of forming a first doped layer, a second doped layer and a third doped layer on a prefabricated film layer according to another embodiment of the present disclosure.

FIG. 5 is a schematic diagram of the structure of a film according to another embodiment of the present disclosure.

FIG. 6 is a schematic diagram of the structure of a photoelectric device according to an embodiment of the present disclosure.

### DETAILED DESCRIPTION

Technical solutions in embodiments of the present disclosure will be clearly and completely described below in conjunction with drawings in the embodiments of the present disclosure. Obviously, the described embodiments are only a part of embodiments of the present disclosure, rather than all the embodiments. Based on the embodiments in the present disclosure, all other embodiments obtained by those skilled in the art without creative work fall within the protection scope of the present disclosure.

Additionally, in the description of the present disclosure, the term “comprising/including” means “comprising/including but not limited to.” Various embodiments of the present disclosure may be presented in a form of range. It should be understood that the description in the form of range is merely for convenience and brevity, and should not be construed as a hard limitation on the scope of the disclosure. Accordingly, it should be considered that the recited range description has specifically disclosed all possible subranges, as well as a single numerical value within that range. For example, it should be considered that a description of a range from 1 to 6 has specifically disclosed subranges, such as from 1 to 3, from 1 to 4, from 1 to 5, from 2 to 4, from 2 to 6, from 3 to 6, etc., and a single number within the range, such as 1, 2, 3, 4, 5, and 6, regardless of the range. Whenever a range of values is indicated herein, it is meant to include any recited number (fraction or integer) within the indicated range.

In the present disclosure, the term “and/or” is used to describe the association of associated objects, and means that there may be three relationships, for example, “A and/or B” may refer to three cases: the first case refers to the presence of A alone; the second case refers to the presence of both A and B; the third case refers to the presence of B alone, where A and B may be singular or plural.

In the present disclosure, the term “at least one” refers to one or more, and “a plurality of/multiple” refers to two or more. The terms “at least one”, “at least one of the followings”, or the like, refer to any combination of the items listed, including any combination of the singular or the plural items. For example, “at least one of a, b, or c” or “at least one of a, b, and c” may refer to: a, b, c, a-b (i.e., a and b), a-c, b-c, or a-b-c, where a, b, and c may be single or plural.

In the present disclosure, the single bond connected with the substituent penetrates through the corresponding ring, which means that the substituent could be connected to any position of the ring. For example, in

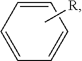

R runs through benzene ring, which means that R could be connected to any substitutable site on benzene ring.

The present disclosure discloses a film, a material of the film includes an organic p-type semiconductor material and a dopant, and the dopant is selected from one or more of a polycyano conjugated compound and a polytrifluoromethyl conjugated compound.

It should be noted that the polycyano conjugated compound contains at least two cyano groups, and the polytrifluoromethyl conjugated compound contains at least two trifluoromethyls. Conjugation refers to the dislocation of electrons when two or more double bonds (or triple bonds) are connected by a single bond. Conjugation could improve the electron-absorbing ability and conductivity of polycyano-conjugated compounds and polytrifluoromethyl-conjugated compounds.

In the film provided by this present disclosure, the polycyano conjugated compound and the polytrifluoromethyl conjugated compound have strong electron absorption capacity and deep LUMO energy level, and could effectively promote the charge transfer between the dopant and the organic p-type semiconductor material, and electrons could be transferred from the organic P-type semiconductor material to the dopant, thereby improving the hole mobility of the film.

In some embodiments, the polycyano conjugated compound is selected from one or more of formula (I), formula (II), formula (III) and formula (IV):

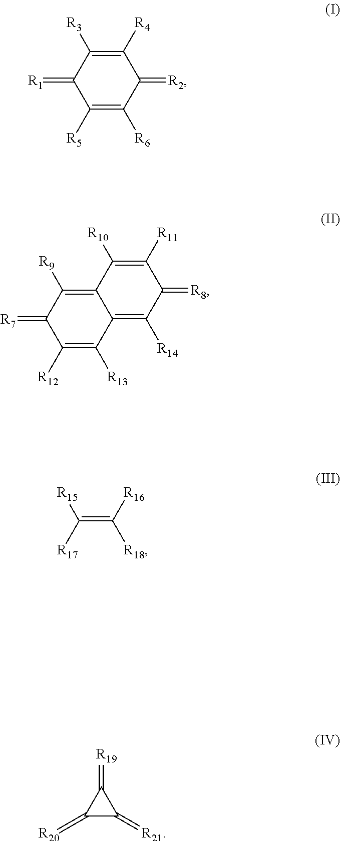

Wherein, R₁, R₂, R₇, R₈, R₁₉, R₂₀, R₂₁ is each independently selected from the group consisting of oxygen or

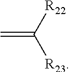

R₃, R₄, R₅, R₆, R₉, R₁₀, R₁₁, R₁₂, R₁₃, R₁₄, R₁₅, R₁₆, R₁₇, R₁₈, R₂₂, R₂₃ is each independently selected from one or more of cyano, halogen, ester, acyl, aldehyde, carboxyl, carbonyl, amido, sulfonic acid, nitro and quaternary amino groups.

Wherein, when R₂₂, R₂₃ and R₃, R₄, R₅, R₆ appear, at least two of them are simultaneously selected from cyano.

When R₂₂, R₂₃ and R₉, R₁₀, R₁₁, R₁₂, R₁₃, R₁₄ appear, at least two of them are simultaneously selected from cyano.

When R₁₅, R₁₆, R₁₇, R₁₈ appear, at least two of them are simultaneously selected from cyano.

When R₁₉, R₂₀, R₂₁ appear, at least one is selected from

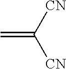

or at least two are selected from

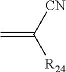

at the same time, and R₂₄ is selected from one or more of halogen group, ester group, acyl group, aldehyde group, carboxyl group, carbonyl group, amido group, sulfonic group, nitro group and quaternary amine group.

In some embodiments, the

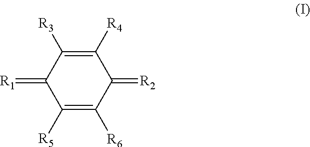

is selected from one or more of

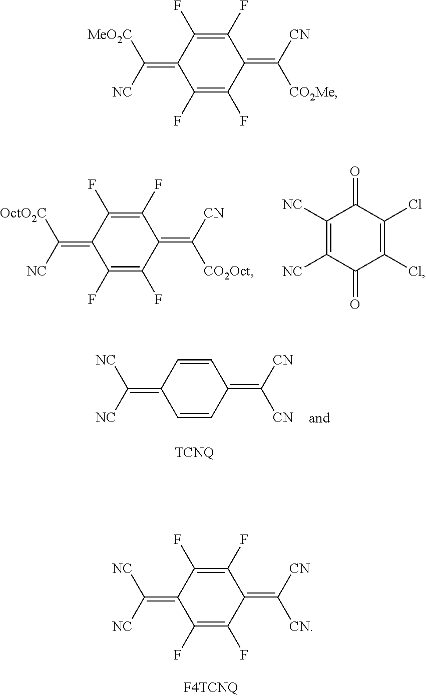

It could be understood that -Me is methyl and -Oct is octyl.

The synthetic route of

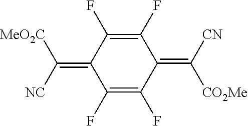 [SMILES: COC(=O)C(C#N)=c1c(F)c(F)c(=C(C#N)C(=O)OC)c(F)c1F]

is as follows:

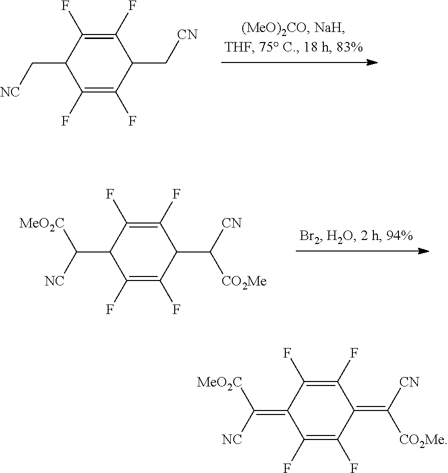 [SMILES: N#CCC1C(F)=C(F)C(CC#N)C(F)=C1F ; COC(=O)C(C#N)C1C(F)=C(F)C(C(C#N)C(=O)OC)C(F)=C1F ; COC(=O)C(C#N)=c1c(F)c(F)c(=C(C#N)C(=O)OC)c(F)c1F]

The specific preparation method of

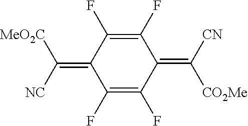 [SMILES: COC(=O)C(C#N)=c1c(F)c(F)c(=C(C#N)C(=O)OC)c(F)c1F]

includes: slowly adding NaH (320 mg, 8.0 mmol) into anhydrous THF (10 mL) solution of 1,4-bis(cyanomethyl)-2,3,5,6-tetrafluorobenzene (CAS: 1000535-69-2, 456 mg, 2.00 mmol) at 0° C. Bringing the mixture to room temperature and stirring it for 30 min, heating it to 75° C. and stirring it for 18 h, then quenching the reaction with 1 mol/L HCl (50 mL), and extracted with ethyl acetate (3×150 mL) for three times. Washing the obtained yellow-green organic extract with brine, drying with Na₂SO₄, filtering, and evaporating the solvent. Purifying the residue by column chromatography. Then, the purified product was suspended in water (10 mL), then saturated bromine aqueous solution (40 mL) was added in stages, stirred vigorously at room temperature for 2 hours, and excess bromine was removed under vacuum. The remaining mixture was extracted with chloroform (3×20 mL) for three times, washed with water, and the solvent was evaporated to obtain

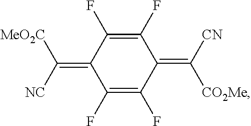 [SMILES: COC(=O)C(C#N)=c1c(F)c(F)c(=C(C#N)C(=O)OC)c(F)c1F]

and its ¹H NMR (500 MHz, CDCl₃) is β 4.04 (s, 6H).

The synthetic route of

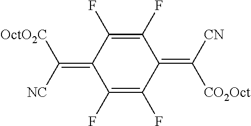

is as follows:

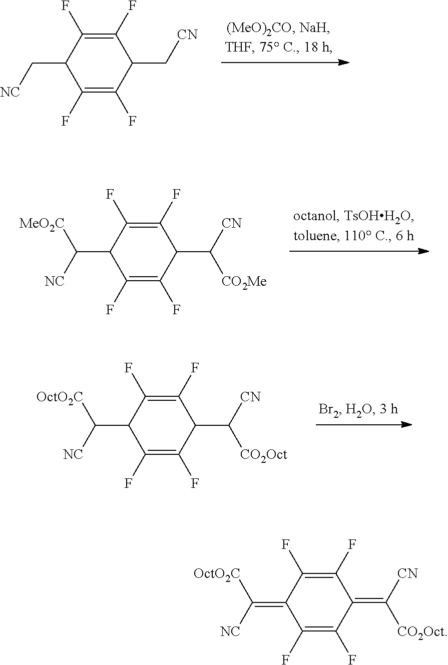

The preparation method of

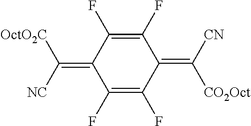

includes:

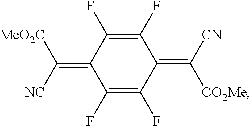 [SMILES: COC(=O)C(C#N)=c1c(F)c(F)c(=C(C#N)C(=O)OC)c(F)c1F]

was prepared according to the above method.

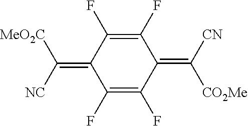 [SMILES: COC(=O)C(C#N)=c1c(F)c(F)c(=C(C#N)C(=O)OC)c(F)c1F]

(344 mg, 1.00 mmol), 1-octanol (6.3 mL, 5.2 g, 40 mmol) and TsOH·H₂O (p-toluenesulfonic acid monohydrate, 19 mg, 0.10 mmol) were added to the reaction flask, and 30 mL toluene solvent was added to react at 110° C. for 6 h, then the solvent was removed in vacuum, and the residue was chromatographed (30% ethyl acetate was dissolved in hexane) and left to solidify. Suspend the solidified substance (270 mg, 0.50 mmol) in water (10 mL), then add saturated bromine aqueous solution (40 mL) in stages, stir vigorously at room temperature for 3h, remove excess bromine under vacuum, extract the remaining mixture with chloroform (3×20 mL), wash it with water, and evaporate the solvent to obtain

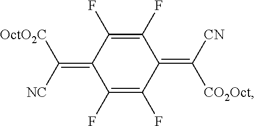

and its ¹H NMR (500 MHz, CDCl₃) is δ2.30 (m, 4H), 1.25-1.55 (m, 24H), 0.88 (t, 6H).

In some embodiments, the

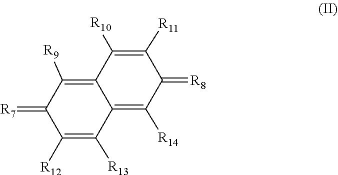

is selected from

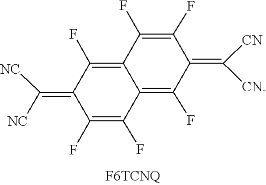 [SMILES: N#CC(C#N)=c1c(F)c(F)c2c(F)c(=C(C#N)C#N)c(F)c(F)c2c1F]

In some embodiments, the

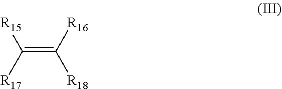

is selected from

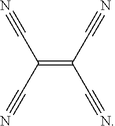

In some embodiments, the

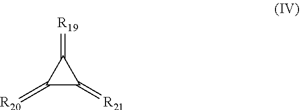

is selected from

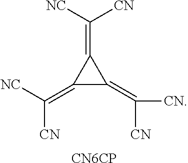 [SMILES: "CN6CP" ; N#CC(C#N)=C1C(=C(C#N)C#N)C1=C(C#N)C#N]

In some embodiments, the polytrifluoromethyl conjugated compound is selected from formula (V):

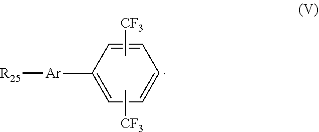

Wherein, R₂₅ is selected from one or more of hydrogen group, deuterium group, halogen group, ester group, acyl group, aldehyde group, carboxyl group, carbonyl group, amido group, sulfonic acid group, nitro group, quaternary amine group and

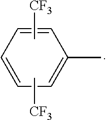

Ar is selected from substituted or unsubstituted aryl with 6-60 ring atoms, substituted or unsubstituted heteroaryl with 5-60 ring atoms, or their combination. Heteroatom in the heteroaryl group include one or more of O, P, N and S.

In some embodiments, Ar is selected from one or more of phenyl, biphenyl, terphenyl, naphthyl, anthracenyl, phenanthryl, carbazolyl, benzocarbazolyl, triphenylamine, thienyl, furyl, pyrrolyl, benzofuran, benzothiophenyl, benzopyrrolyl, pyridyl and spirobifluorene.

In some embodiments, the substituted substituent is selected from one or more of halogen group, ester group, acyl group, aldehyde group, carboxyl group, carbonyl group, amido group, sulfonic group, nitro group and quaternary amine group.

In some embodiments, the

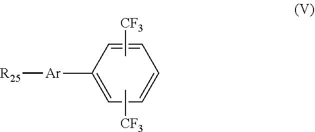

is selected from one or more of

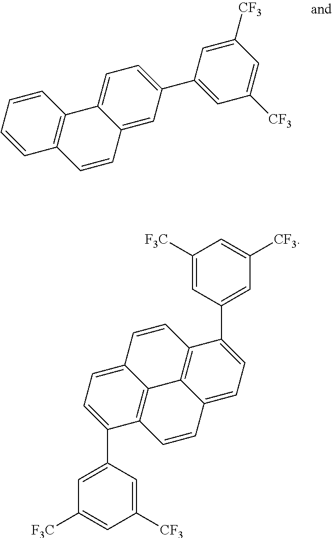 [SMILES: FC(F)(F)c1cc(-c2ccc3c(ccc4ccccc43)c2)cc(C(F)(F)F)c1 ; FC(F)(F)c1cc(-c2ccc3ccc4c(-c5cc(C(F)(F)F)cc(C(F)(F)F)c5)ccc5ccc2c3c54)cc(C(F)(F)F)c1]

In some embodiments, the film includes at least two film layers, and a mass fraction of the dopant in each film layer tends to increase or decrease in the same direction. In other words, the mass fraction of dopant in any adjacent film layer increases in the same direction in turn, forming gradient doping, which makes the energy level of the film layer change gradient and is beneficial to hole transport.

In some embodiments, the organic p-type semiconductor material includes a first organic p-type semiconductor material, and the film includes a first film layer 21 and a second film layer 22 which are stacked, wherein a material of the first film layer 21 includes the first organic p-type semiconductor material, and a material of the second film layer 22 includes the first organic p-type semiconductor material and the dopant. In other words, the first film layer 21 contains no dopant.

In other embodiments, the organic p-type semiconductor material includes a first organic p-type semiconductor material and a second organic p-type semiconductor material, and the film includes a first film layer 21, a second film layer 22 . . . a 2M film layer and a 2M+1 film layer which are stacked. A material of the first film layer 21 includes the first organic p-type semiconductor material, and the second film layer 22 to the 2M+1 film layer all includes the second organic p-type semiconductor material and the dopant, and in any two adjacent films from the second film layer 22 to the 2M+1 film layer, a mass fraction of the dopant in the latter film layer is greater than that in the previous film layer. It should be noted that the second film layer 22 also includes a first organic p-type semiconductor material. In other words, a content of the dopant in each film layer increases from the second film layer to the 2M+1 film layer.

It should be noted that in the present disclosure, the “mass fraction of the dopant in the film” means a mass ratio of the dopant in the film to all materials in the film.

The first organic p-type semiconductor material is the same as or different from the second organic p-type semiconductor material.

The second organic p-type semiconductor materials in different film layers are the same or different.

The dopants in different film layers are the same or different.

In some embodiments, the first organic p-type semiconductor material and the second organic p-type semiconductor material in different film layers is independently selected from one or more of 4,4′-N,N′-dicarbazolyl-biphenyl, N,N′-diphenyl-N,N′-bis (1-naphthyl)-1,1′-biphenyl)-4,4′-diamine, N,N′-bis (3-methylphenyl)-N,N′-bis (phenyl)-spiro, N,N′-bis (4-(N,N′-diphenyl-amino) phenyl)-N,N′-diphenylbenzidine, 4,4′,4′-tris (N-carbazolyl)-triphenylamine, 4,4′,4′-tris (carbazole-9-yl)triphenylamine, trichloroisocyanuric acid, terbium-doped phosphate-based green luminescent material, 2,3,6,7,10,11-hexacyano-1,4,5,8,9,12-hexaazaphenanthrene, 4,4′,4′-tris (N-3-methylphenyl-N-phenylamino) triphenylamine, poly [(9,9′-dioctyl fluorene-2,7-diyl)-co-(4, 4′-(N-(4-sec-butylphenyl) diphenylamine))], poly (4-butylphenyl-diphenylamine), poly [bis(4-phenyl) (4-butylphenyl) amine], polyaniline, polypyrrole, poly (p) phenylene vinylene, poly (phenylene vinylene), poly [2-methoxy-5-(2-ethylhexyloxy)-1,4-phenylene vinylene], poly [2-methoxy-5-(3′,7′-dimethyl octyloxy)-1,4-phenylene vinylene], copper phthalocyanine, aromatic tertiary amine, 4,4′-bis (p-carbazolyl)-1,1′-biphenyl compound, N,N,N′,N′-tetraarylbenzidine, poly (9,9-dioctylfluorene-alt-N-(4-sec-butylphenyl)-diphenylamine), PEDOT, PEDOT:PSS and its derivatives, PEDOT: PSS derivatives doped with s-MoO₃, poly (N-vinylcarbazole) and its derivatives, polymethacrylate and its derivatives, poly (9,9-octylfluorene) and its derivatives, poly (spirofluorene) and its derivatives, N,N′-bis (naphthalene-1-yl)-N,N′-diphenylbenzidine, spiro NPB, microcrystalline cellulose and tetracyanoquinone dimethylmethane.

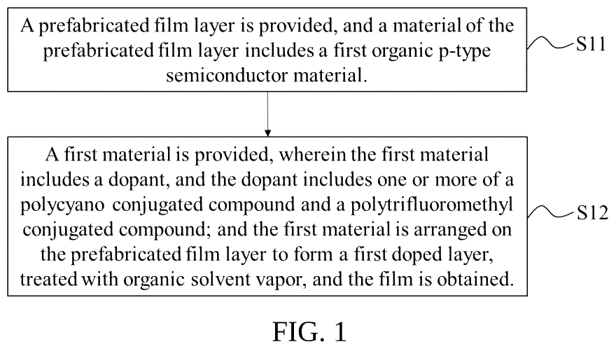

Referring to FIG. 1, the present disclosure proposes a preparation method of a film which includes step S11-S12.

In step S11, a prefabricated film layer 20 is provided, and a material of the prefabricated film layer 20 includes a first organic p-type semiconductor material.

In step S12, a first material is provided, wherein the first material includes a dopant, and the dopant is selected from one or more of a polycyano conjugated compound and a polytrifluoromethyl conjugated compound; and the first material is arranged on the prefabricated film layer to form a first doped layer 30, treated with organic solvent vapor, and the film is obtained.

In some embodiments, a thickness of the prefabricated film layer 20 is 20 nm-50 nm, such as 22 nm, 48 nm, 25 nm, 45 nm, 28 nm, 40 nm, 30 nm, 38 nm, 32 nm and 35 nm, etc. It should be noted that in the present disclosure, thickness of film layer is measured by a step tester.

In some embodiments, a treatment time of the organic solvent vapor ranges between 1 min-30 min, such as 2 min, 28 min, 5 min, 25 min, 8 min, 22 min, 10 min, 20 min, 12 min and 15 min. Within the time range, it is beneficial for the organic solvent vapor to fully corrode the dopant.

In some embodiments, the organic solvent vapor is selected from one or more of carbon disulfide, chloroform, dichloromethane, ethyl acetate and tetrahydrofuran. It could be understood that the first organic p-type semiconductor material is an organic substance, which could be dissolved in the organic solvent vapor, thus increasing the free volume of the first organic p-type semiconductor material, while the dopant is one or more of polycyano-based conjugated compound and polytrifluoromethyl-based conjugated compound, which are small in volume and easy to penetrate between molecules of the first organic p-type semiconductor material after being treated by the organic solvent vapor, thus forming a mixed film layer of the dopant and the first organic p-type semiconductor material.

In some embodiments, treatment with the organic solvent vapor includes: introducing the organic solvent vapor.

In other implementations, treatment with the organic solvent vapor includes: placing in the organic solvent vapor atmosphere.

In some embodiments, after treatment with the organic solvent vapor, the method further includes thermal annealing.

In some embodiments, a temperature of the thermal annealing ranges between 100° C.-250° C., such as 120° C., 240° C., 140° C., 220° C., 150° C., 200° C., 160° C., 190° C., 170° C., 180° C., etc. A time of the thermal annealing ranges between 10 min-60 min, such as 12 min, 58 min, 15 min, 55 min, 20 min, 50 min, 25 min, 45 min, 30 min, 40 min, etc.

By controlling the treatment time of organic solvent vapor, the type of organic solvent vapor and the conditions of thermal annealing, the mixing degree of the dopant and the first organic p-type semiconductor material could be effectively controlled.

In some embodiments, a thickness of the first doped layer 30 is 5 nm-20 nm, such as 6 nm, 18 nm, 7 nm, 16 nm, 8 nm, 15 nm, 10 nm, 14 nm, 12 nm, 13 nm, etc.

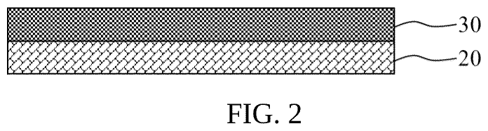

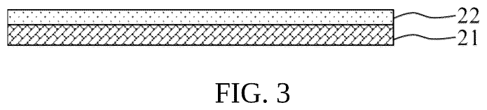

Referring to FIG. 2 and FIG. 3, in some embodiments, the forming of the first doped layer 30 includes disposing the dopant on the prefabricated film layer 20 to form the first doped layer 30.

In some embodiments, the forming of the first doped layer 30 includes: the dopant and a solvent are provided and mixed to obtain a dopant dispersion, and the dopant dispersion is set on the prefabricated film layer 20 to form the first doped layer 30.

In some embodiments, a mass concentration of the dopant in the dopant dispersion ranges between 1 mg/mL-5 mg/mL, such as 1.5 mg/mL, 4.5 mg/mL, 2 mg/mL, 4.2 mg/mL, 2.5 mg/mL, 4 mg/mL, 2.8 mg/mL and 3.5 mg/mL. Within the mass concentration range, it is beneficial to the uniform dispersion of the dopant.

In some embodiments, the solvent is selected from one or more of dimethylformamide, dimethyl sulfoxide, sulfolane, ethylene nitrate, xylene, anisole, decalin, cyclohexane, cyclohexene, methylcyclohexane, ethylcyclohexane, limonene, hexane, octane, nonane, decane, dimethylacetamide, acetyl carbonate, N-methylpyrrolidone, tetrahydrofuran, ethyl acetate and dichloromethane.

In some embodiments, after treatment with the organic solvent vapor, the film and a sub-doped layer located on the film are obtained, and a material of the sub-doped layer includes the dopant. The preparation method of the film further includes removing the sub-doped layer to obtain the film.

In some embodiments, a method for removing the sub-doped layer includes vacuumizing or solvent cleaning.

It could be understood that the film includes a first film layer 21 and a second film layer 22 which are stacked, wherein a material of the first film layer 21 includes the first organic p-type semiconductor material which is not infiltrated with the dopant, and a material of the second film layer 22 includes the first organic p-type semiconductor material and the dopant doped in the first organic p-type semiconductor material.

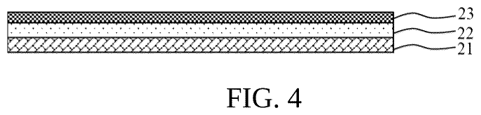

Referring to FIG. 4, in other embodiments, the first material further includes a second organic p-type semiconductor material. After treatment with the organic solvent vapor, a first film layer 21, a second film layer 22 and a third film layer 23 are obtained. A material of the first film layer 21 includes the first organic p-type semiconductor material, a material of the second film layer 22 includes the first organic p-type semiconductor material, the second organic p-type semiconductor material and the dopant, and a material of the third film layer 23 includes the second organic p-type semiconductor material and the dopant, and a mass fraction of the dopant in the third film layer 23 is greater than that in the second film layer 22.

In some embodiments, after obtaining the third film layer 23, it further includes forming at least one film layer on the third film layer 23. Wherein, each of the film layer includes the second organic p-type semiconductor material and the dopant, and in any two adjacent film layers in the direction from the second film layer 22 to the third film layer 23, a mass fraction of the dopant in the latter film layer is greater than that in the previous film layer.

In some embodiments, a method for forming the film layer includes the following steps: providing an M material, wherein the M material includes a second organic p-type semiconductor material and a dopant, and a mass fraction of the dopant in the M material is greater than that in the previous film layer.

The M material is arranged on the previous film layer to form an M doped layer, and an organic solvent vapor treatment is adopted to obtain a 2M film layer and a (2M+1) film layer, wherein M is an integer greater than or equal to 2.

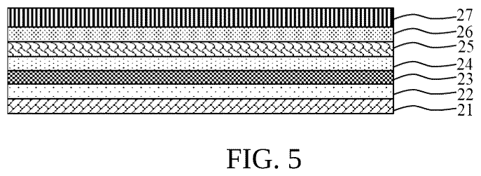

Illustratively, referring to FIG. 5, in at least one embodiment, M=3, the film includes a first film layer 21, a second film layer 22, a third film layer 23, a fourth film layer 24, a fifth film layer 25, a sixth film layer 26 and a seventh film layer 27 which are arranged in a stacked manner. Moreover, a concentration of the dopant increases in turn along the direction from the first film layer 21 to the seventh film layer 27, which is beneficial to the formation of gradient energy levels and the promotion of hole transport.

It could be understood that after setting the first doped layer 30, the first film layer 21 infiltrated into the prefabricated film layer 20 and the second film layer 22 not infiltrated will be formed. In other words, each doped layer will be treated to form two films, and the prefabricated film layer 20 will retain the first film layer 21. Therefore, after setting the M doped layers, a total of 2M+1 film layers will eventually be formed.

It should be noted that the organic solvent vapor used to treat different doped layers is the same or different. The treatment time of the organic solvent vapor on different doped layers is the same or different.

In some embodiments, after each doped layer is formed, a treatment time of the organic solvent vapor ranges between 1 min-30 min independently, such as 2 min, 28 min, 5 min, 25 min, 8 min, 22 min, 10 min, 20 min, 12 min and 15 min. It should be noted that each treatment with organic solvent vapor could be selected according to the thickness and doping depth.

It could be understood that the doped layer could be formed by conventional techniques in the field, such as chemical method or physical method. Among them, chemical methods include chemical vapor deposition, continuous ion layer adsorption and reaction, anodic oxidation, electrolytic deposition and coprecipitation. Physical methods include physical coating method and solution method, in which physical coating method includes thermal evaporation coating method, electron beam evaporation coating method, magnetron sputtering method, multi-arc ion coating method, physical vapor deposition method, atomic layer deposition method, pulsed laser deposition method, etc. The solution method could be spin coating method, printing method, ink-jet printing method, blade coating method, printing method, dipping and pulling method, soaking method, spraying method, roller coating method, casting method, slit coating method and strip coating method.

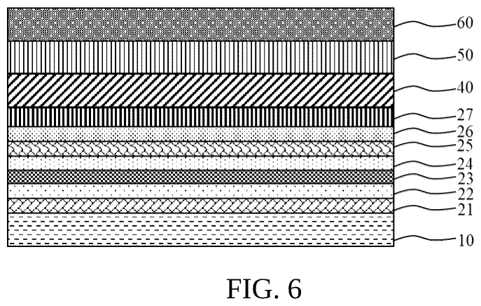

Referring to FIG. 6, the present disclosure discloses a photoelectric device, including:
an anode 10;
an active layer 40, located on the anode 10;
a cathode 20, located on the active layer 40; and
a hole functional layer located between the anode 10 and the active layer 40, wherein the hole functional layer includes the film or the film prepared by the preparation method.

It could be understood that the organic p-type semiconductor material in the film is a hole functional material.

In the photoelectric device provided by the present disclosure, the hole functional layer includes a hole functional material doped with a polycyano conjugated compound and a polytrifluoromethyl conjugated compound, wherein the polycyano conjugated compound and the polytrifluoromethyl conjugated compound have strong electron absorption capacity and a deep LUMO energy level, so that the hole mobility of the hole functional layer could be improved, the injection barrier of holes migrating from the hole functional layer to the active layer 40 could be reduced, the recombination of holes and electrons could be promoted, and the photoelectric efficiency of the photoelectric device could be further improved and prolonged.

In some embodiments, the film includes at least two film layers, and a mass fraction of the dopant in each film layer increases in turn along the direction from the anode 10 to the active layer 40.

In some embodiments, the organic p-type semiconductor material includes a first organic p-type semiconductor material, and the film includes a first film layer 21 and a second film layer 22 which are stacked, wherein the first film layer 21 is arranged between the anode and the second film layer 22, and a material of the first film layer 21 includes the first organic p-type semiconductor material, and a material of the second film layer 22 includes the first organic p-type semiconductor material and the dopant.

In other embodiments, the organic p-type semiconductor material includes a first organic p-type semiconductor material and a second organic p-type semiconductor material, and the film includes a first film layer 21, a second film layer 22 . . . a 2M film layer and a 2M+1 film layer which are stacked along the direction from the anode 10 to the active layer 40. A material of the first film layer 21 includes the first organic p-type semiconductor material, and the second film layer 22 to the 2M+1 film layer all includes the second organic p-type semiconductor material and the dopant, and in any two adjacent film layers from the second film layer 22 to the 2M+1 film layer, a mass fraction of the dopant in each film layer increases in turn along the direction from the anode 10 to the active layer 40.

A material of the anode 10 and the cathode 60 is each independently selected from one or more of metal, carbon material and metal oxide. The metal is selected from one or more of Al, Ag, Cu, Mo, Au, Ba, Ca, Yb and Mg. The carbon material is selected from one or more of graphite, carbon nanotubes, graphene and carbon fiber. The metal oxide is selected from one or more of metal oxide electrode or composite electrode with metal sandwiched between doped or undoped transparent metal oxide, and a material of the metal oxide electrode is selected from one or more of ITO, FTO, ATO, AZO, GZO, IZO, MZO, MoO₃ and AMO. The composite electrode is selected from one or more of AZO/Ag/AZO, AZO/Al/AZO, ITO/Ag/ITO, ITO/Al/ITO, ZnO/Ag/ZnO, ZnO/Al/ZnO, ZnS/Ag/ZnS, ZnS/Al/ZnS, TiO₂/Ag/TiO₂ and TiO₂/Al/TiO₂. Where “/” represents a laminated structure, for example, AZO/Ag/AZO represents a composite electrode including an AZO layer, an Ag layer and an AZO layer which are sequentially laminated.

In some embodiments, a thickness of the anode 10 is 10 nm-80 nm, such as 15 nm, 75 nm, 20 nm, 70 nm, 25 nm, 60 nm, 30 nm, 50 nm, 35 nm and 40 nm, etc.

In some embodiments, the active layer 40 includes a luminescent layer, a material of the luminescent layer is selected from one or more of organic luminescent material and quantum dot luminescent material.

A material of the organic luminescent material is selected from one or more of CBP:Ir(mppy)₃(4,4′-bis (N-carbazole)-1,1′-biphenyl: tris [2-(p-tolyl) pyridine iridium (III)]), TCTX:Ir(mmpy)(4,4′), 4″-tris (carbazole-9-yl)triphenylamine: tris [2-(p-tolyl) iridium pyridine]), diarylanthracene derivatives, stilbene aromatic derivatives, pyrene derivatives, fluorene derivatives, TBPe fluorescent materials, TTPX fluorescent materials, TBRb fluorescent materials, DBP fluorescent materials, delayed fluorescent materials, TTA materials, TADF (delayed thermal activation) materials, polymers containing B—N covalent bonds, HLCT (hybrid local charge transfer excited state) materials and Exciplex luminescent materials.

The quantum dot luminescent material could be selected from but not limited to one or more of single-structure quantum dot, core-shell quantum dot and perovskite-type semiconductor material.

A material of the single-structure quantum dot, a core material of the core-shell quantum dot and a shell material of the core-shell quantum dot could be respectively selected from but not limited to one or more of second II-VI compound, second IV-VI compound, second III-V compound and IIII-VI compound. A shell layer of the core-shell structure quantum dot comprises one or more layers. The second II-VI compound is selected from one or more of CdS, CdSe, CdTe, ZnS, ZnSe, ZnTe, HgS, HgSe, HgTe, CdSeS, CdSeTe, CdSTe, ZnSeS, ZnSeTe, ZnSTe, HgSeS, HgSeTe, HgSTe, CdZnS, CdZnSe, CdZnTe, CdHgS, CdHgSe, CdHgTe, HgZnS, HgZnSe, HgZnTe, CdZnSeS, CdZnSeTe, CdZnSTe, CdHgSeS, CdHgSeTe, CdHgSTe, HgZnSeS, HgZnSeTe and HgZnSTe. The second IV-VI compound is selected from one or more of SnS, SnSe, SnTe, PbS, PbSe, PbTe, SnSeS, SnSeTe, SnSTe, PbSeS, PbSeTe, PbSTe, SnPbS, SnPbSe, SnPbTe, SnPbSSe, SnPbSeTe and SnPbSTe. The second III-V compound is selected from one or more of GaN, GaP, GaAs, GaSb, AlN, AlP, AlAs, AlSb, InN, InP, InAs, InSb, GaNP, GaNAs, GaNSb, GaPAs, GaPSb, AlNP, AlNAs, AlNSb, AlPAs, AlPSb, InNP, InNAs, InNSb, InPAs, InPSb, GaAlNP, GaAlNAs, GaAlNSb, GaAlPAs, GaAlPSb, GaInNP, GaInNAs, GaInNSb, GaInPAs, GaInPSb, InAlNP, InAlNAs, InAlNSb, InAlPAs and InAlPSb. The I-III-VI compound is selected from one or more of CuInS₂, CuInSe₂ and AgInS₂.

As an example, the core-shell quantum dot is selected from one or more of CdSe/CdSeS/CdS, InP/ZnSeS/ZnS, CdZnSe/ZnSe/ZnS, CdSe/ZnS, CdSe/ZnSe, ZnSe/ZnS, ZnSe/ZnS, ZnSe/ZnS, and ZnSe/ZnSe/ZnSe.

The perovskite semiconductor material is selected from one of doped or undoped inorganic perovskite semiconductor or organic-inorganic hybrid perovskite semiconductor. A general structural formula of the inorganic perovskite semiconductor is AMX₃, wherein A is Cs⁺, and X is divalent metal cation, which is selected from one or more of Pb²⁺, Sn²⁺, Cu²⁺, Ni²⁺, Cd²⁺, Cr²⁺, Mn²⁺, Co²⁺, Fe²⁺, Ge²⁺, Yb²⁺ and Eu²⁺, and X is a halogen anion selected from one or more of Cl⁻, Br⁻ and I⁻. The general structural formula of the organic-inorganic hybrid perovskite semiconductor is BMX₃, wherein B is an organic amine cation selected from CH₃(CH₂)ₙ₋₂NH³⁺ or [NH₃(CH₂)ₙNH₃]²⁺, wherein n≥2, and M is a divalent metal cation selected from Pb²⁺, Sn²⁺, Cu²⁺, Ni²⁺, Cd²⁺ and Cr³⁺, and X is a halogen anion selected from one or more of Cl, Br and I.

In some embodiments, a thickness of the active layer 40 is 10 nm-50 nm, such as 12 nm, 48 nm, 15 nm, 45 nm, 18 nm, 40 nm, 20 nm, 35 nm, 25 nm and 30 nm, etc.

In some embodiments, a thickness of the cathode 60 is 15 nm-100 nm, such as 20 nm, 90 nm, 25 nm, 85 nm, 30 nm, 80 nm, 40 nm, 70 nm, 50 nm and 60 nm, etc.

In some embodiments, the photoelectric device further includes an electronic functional layer 50 disposed between the active layer 40 and the cathode 60.

In some embodiments, the electronic functional layer 50 is selected from one or more of an electronic injection layer and an electronic transport layer.

In some embodiments, a material of the electronic functional layer 50 is selected from one or more of first doped metal oxide particle, first undoped metal oxide particle, IIB-VIA semiconductor material, IIIA-VA semiconductor material and IB-IIIA-VIA semiconductor material. A material of the first undoped metal oxide particle is selected from one or more of ZnO, TiO₂, SnO₂, ZrO₂ and Ta₂O₅. A metal oxide in the first doped metal oxide particle is selected from one or more of ZnO, TiO₂, SnO₂, ZrO₂, Ta₂O₅ and Al₂O₃. A doping element in the first doped metal oxide particle is selected from one or more of Al, Mg, Li, Mn, Y, La, Cu, Ni, Zr, Ce, In and Ga. The IIB-VIA semiconductor material is selected from one or more of ZnS, ZnSe and CdS. The IIIA-VA semiconductor material is selected from one or more of InP and GaP. The IB-IIIA-VIA family semiconductor material is selected from one or more of CuInS and CuGaS.

In some embodiments, a thickness of the electronic functional layer 50 is 20 nm-40 nm, such as 22 nm, 38 nm, 25 nm, 36 nm, 28 nm, 35 nm, 30 nm, 34 nm, 31 nm and 32 nm, etc.

The present disclosure also discloses a display device, including the photoelectric device in any of the above embodiments.

The display device could be a mobile terminal such as a TV set, a mobile phone, a tablet computer, a computer monitor, or a device with a display screen such as a game device, an Augmented Reality (AR) device, a Virtual Reality (VR) device, a data storage device, an audio playback device, a video playback device, and a wearable device, wherein the wearable device could be a smart bracelet, smart glasses, and a smart watch.

This present disclosure will be explained in detail by specific examples. The following examples are only partial examples of this present disclosure, and are not limited to this present disclosure.

### Example 1

This example provides a film, and a preparation method of the film includes steps S1-S3.

In step S1, a substrate is provided.

In step S2, 10 mg/mL TFB (poly(9,9-dioctylfluorene-alt-N-(4-sec-butylphenyl)-diphenylamine)) solution is placed on the substrate, and spin-coating was carried out at the rotating speed of 2500 rpm for 30s, followed by annealing at 150° C. for 15 min to form a 30 nm prefabricated film layer.

In step S3, 3 mg/ml of

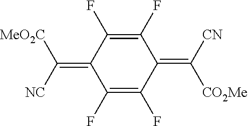 [SMILES: COC(=O)C(C#N)=c1c(F)c(F)c(=C(C#N)C(=O)OC)c(F)c1F]

solution is placed on the prefabricated membrane layer, put it in a petri dish containing carbon disulfide vapor, cover it, leave aside for 5 min and then take it out, and heat at 200° C. for 30 min. Vacuumizing to remove residual

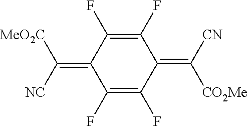 [SMILES: COC(=O)C(C#N)=c1c(F)c(F)c(=C(C#N)C(=O)OC)c(F)c1F]

on the surface. A first film layer and a second film layer located on the substrate are obtained, and a material of the first film layer includes TFB, a material of the second film layer includes

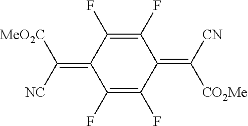 [SMILES: COC(=O)C(C#N)=c1c(F)c(F)c(=C(C#N)C(=O)OC)c(F)c1F]

and TFB, and the film is obtained.

### Example 2

This example is basically the same as Example 1, only the difference is that in this example,

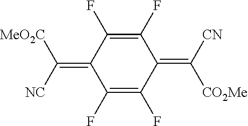 [SMILES: COC(=O)C(C#N)=c1c(F)c(F)c(=C(C#N)C(=O)OC)c(F)c1F]

is replaced by F4-TCNQ.

### Example 3

This example is basically the same as Example 1, only the difference is that in this example,

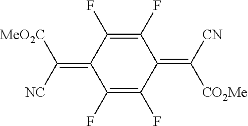 [SMILES: COC(=O)C(C#N)=c1c(F)c(F)c(=C(C#N)C(=O)OC)c(F)c1F]

is replaced by

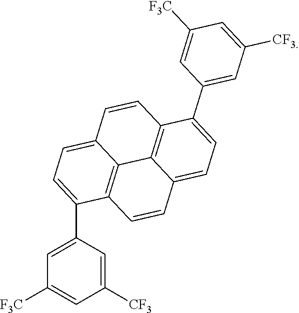 [SMILES: FC(F)(F)c1cc(-c2ccc3ccc4c(-c5cc(C(F)(F)F)cc(C(F)(F)F)c5)ccc5ccc2c3c54)cc(C(F)(F)F)c1]

### Example 4

This example is basically the same as Example 1, only the difference is that in this example, TFB is replaced by PVK (poly (N-vinylcarbazole)).

### Example 5

This example is basically the same as Example 2, only the difference is that in this example, carbon disulfide vapor is replaced by tetrahydrofuran vapor.

### Example 6

This example is basically the same as Example 4, only the difference is that in this example, put it in a petri dish containing carbon disulfide vapor, cover it, leave aside for 1 min and then take it out.

### Example 7

This example is basically the same as Example 1, only the difference is that in this example, put it in a petri dish containing carbon disulfide vapor, cover it, leave aside for 30 min and then take it out.

### Example 8

This example is basically the same as Example 1, only the difference is that in this example, after taking the petri dish out, heat at 250° C. for 30 min.

### Example 9

This example is basically the same as Example 1, only the difference is that in this example, after taking the petri dish out, heat at 100° C. for 30 min.

### Example 10

This example is basically the same as Example 1, only the difference is that in this example, after taking the petri dish out, heat at 200° C. for 60 min.

### Example 11

This example is basically the same as Example 1, only the difference is that in this example, after taking the petri dish out, heat at 200° C. for 10 min.

### Example 12

This example is basically the same as Example 1, only the difference is that in this example, S3 is replaced by S31.

In step S31, 30 mL of 10 mg/mL TFB solution and 3 mL of 3 mg/mL

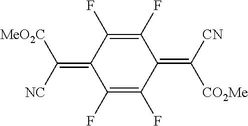 [SMILES: COC(=O)C(C#N)=c1c(F)c(F)c(=C(C#N)C(=O)OC)c(F)c1F]

solution is mixed and placed on the prefabricated membrane layer, a first doped layer is formed. Put it in a petri dish containing carbon disulfide vapor, cover it, leave aside for 5 min and then take it out, and heat at 200° C. for 30 min. A first film layer, a second film layer and a third film layer located on the substrate are obtained, and the film is obtained.

### Example 13

This example is basically the same as Example 12, only the difference is that in this example, after forming the third film layer, further includes: 30 mL of 10 mg/mL TFB solution and 3 mL of 3 mg/mL

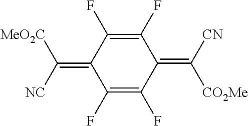 [SMILES: COC(=O)C(C#N)=c1c(F)c(F)c(=C(C#N)C(=O)OC)c(F)c1F]

solution is mixed and placed on the third film layer, a second doped layer is formed. Put it in a petri dish containing carbon disulfide vapor, cover it, leave aside for 5 min and then take it out, and heat at 200° C. for 30 min. A first film layer, a second film layer, a third film layer, a fourth film layer and a fifth film layer located on the substrate are obtained. 30 mL of 10 mg/mL TFB solution and 3 mL of 3 mg/mL

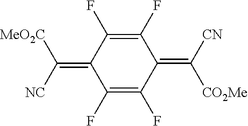 [SMILES: COC(=O)C(C#N)=c1c(F)c(F)c(=C(C#N)C(=O)OC)c(F)c1F]

solution is mixed and placed on the fifth film layer, a third doped layer is formed. Put it in a petri dish containing carbon disulfide vapor, cover it, leave aside for 5 min and then take it out, and heat at 200° C. for 30 min. A first film layer, a second film layer, a third film layer, a fourth film layer, a fifth film layer 1, a sixth film layer and a seventh film layer located on the substrate are obtained, and the film is obtained.

### Example 14

This example is basically the same as Example 13, only the difference is that in this example, the forming of the third doped layer includes: 3 mg/mL

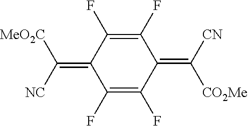 [SMILES: COC(=O)C(C#N)=c1c(F)c(F)c(=C(C#N)C(=O)OC)c(F)c1F]

solution is placed on the second film layer, and a third doped layer is formed.

### Example 15

This example is basically the same as Example 13, only the difference is that in this example,

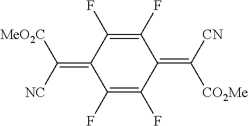 [SMILES: COC(=O)C(C#N)=c1c(F)c(F)c(=C(C#N)C(=O)OC)c(F)c1F]

is replaced by F4-TCNQ.

### Example 16

This example is basically the same as Example 13, only the difference is that in this example,

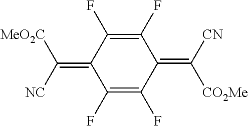 [SMILES: COC(=O)C(C#N)=c1c(F)c(F)c(=C(C#N)C(=O)OC)c(F)c1F]

is replaced by

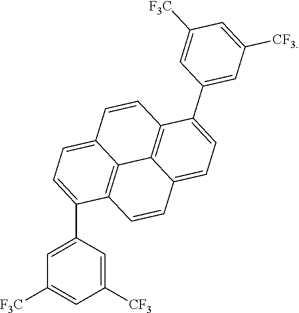 [SMILES: FC(F)(F)c1cc(-c2ccc3ccc4c(-c5cc(C(F)(F)F)cc(C(F)(F)F)c5)ccc5ccc2c3c54)cc(C(F)(F)F)c1]

### Example 17

This example is basically the same as Example 13, only the difference is that in this example, TFB is replaced by PVK.

### Comparative Example 1

This comparative example is basically the same as Example 1, only the difference is the film in Comparative Example 1 is the prefabricated film layer in Example 1.

### Comparative Example 2

This comparative example provides a film, and a preparation method of the film includes steps S4-S5.

In step S4, a substrate is provided.

In step S5, 3 mL of TCNQ solution and 5 mL PEDOT: PSS is mixed and placed on the substrate, and the film is obtained.

### Comparative Example 3

This comparative example is basically the same as Example 13, only the difference is that in this comparative example, without putting it in a petri dish containing carbon disulfide vapor, cover it, leave aside for 5 min and then take it out.

### Performance Test:

A hole mobility of films in Examples 1-17 and Comparative Examples 1-3 were tested, and the results are shown in Table 1.

The testing method of hole mobility includes: testing the current density-voltage curve of single electronic transport film device (HOD), wherein the structure of HOD includes an anode (ITO), a hole transport layer, a luminescent layer (CdZnSeS/ZnS) and a cathode (Ag), and the hole functional layer is the above-mentioned films. The space charge limited current (SCLC) region in the current density-voltage curve is obtained, and then the electron mobility is calculated according to the formula J=(9/8)εᵣε₀μₑV²/d³, where J represents the current density, and the unit is mA cm⁻²; εᵣ represents relative dielectric constant, co represents vacuum dielectric constant; μₑ represents hole mobility in cm²V⁻¹s⁻¹; V represents the driving voltage, in V; D represents the film thickness in m . . .

TABLE 1

| | Hole mobility |
|---|---|
| | (cm²V⁻¹s⁻¹) |
| Example 1 | 1.05 × 10⁻² |
| Example 2 | 8.31 × 10⁻³ |
| Example 3 | 1.21 × 10⁻² |
| Example 4 | 5.28 × 10⁻³ |
| Example 5 | 5.31 × 10⁻³ |
| Example 6 | 4.82 × 10⁻³ |
| Example 7 | 4.12 × 10⁻³ |
| Example 8 | 6.06 × 10⁻³ |
| Example 9 | 3.77 × 10⁻³ |
| Example 10 | 7.82 × 10⁻³ |
| Example 11 | 4.53 × 10⁻³ |
| Example 12 | 4.75 × 10⁻³ |
| Example 13 | 2.15 × 10⁻² |
| Example 14 | 1.23 × 10⁻² |
| Example 15 | 1.89 × 10⁻² |
| Example 16 | 2.47 × 10⁻² |
| Example 17 | 8.94 × 10⁻³ |
| Comparative Example 1 | 3.08 × 10⁻³ |
| Comparative Example 2 | 3.15 × 10⁻³ |
| Comparative Example 3 | 3.62 × 10⁻³ |

From Examples 1-5 and Comparative Examples 1-2, it could be seen that the hole mobility of the film could be effectively improved by organic solvent vapor treatment after the dopant is provided on the preformed film layer. The types of dopants have a certain influence on the properties of films, and the improvement effect of polytrifluoromethyl conjugated compound on film is better than that of polycyano conjugated compound. The effect of carbon disulfide vapor treatment on the film properties is better than that of tetrahydrofuran vapor. Compared with Comparative Example 2, the dopant is directly mixed with the p-type semiconductor material, and in Example 1, the solvent vapor treatment is adopted to make the dopant penetrate into the prefabricated film layer, which could effectively improve the hole mobility of the film.

From Examples 1, 6-11 and Comparative Example 1, it could be seen that the hole mobility of the film could be effectively improved within the time range of carbon disulfide vapor treatment, the temperature range of heat treatment after organic solvent vapor treatment and the time range of heat treatment provided by the present disclosure.

From Examples 1, 12-17 and Comparative Examples 1, 3, it could be seen that the effect of multi-layer doping on improving the hole mobility is better than that of single-layer film. In Examples 13-17, the hole mobility of films with multi-layer films and gradient doping of dopants is significantly improved. Photoelectric device Example 1

This example provides a photoelectric device, and a preparation method of the photoelectric device includes steps S21-S26.

In step S21, an ITO glass is provided, and the surface of the ITO glass is wiped with a cotton swab dipped in a small amount of soapy water to remove impurities visible to the naked eye. Then, it is ultrasonically cleaned with deionized water, acetone, ethanol and isopropanol for 15 min, dried with nitrogen to form 30 nm ITO anode.

In step S22, a film is formed on the ITO anode according to the method of Example 1 to prepare hole functional layer.

In step S23, a quantum dot solution of CdZnSeS/ZnS with a mass concentration of 40 mg/mL is prepared, and then spin-coated on the hole functional layer at the rotating speed of 1500 rpm for 30s, and then heated at 100° C. for 5 min to form 40 nm luminescent layer.

In step S24, a solution of ZnO with a mass concentration of 30 mg/mL is prepared, and then spin-coated on the luminescent layer at the rotating speed of 3000 rpm for 30s, and then heated at 100° C. for 15 min to form 30 nm electronic functional layer.

In step S25, an Al is evaporated by thermal evaporation on the electronic transport layer, vacuum degree is not higher than 3×10⁻⁴ Pa, the speed is 1 Å/s, the time is 100 s, and then an Ag is evaporated to form cathode.

In step S26, a photoelectric device is obtained after packaging. Photoelectric device Examples 2-17

Photoelectric device Examples 2-17 are basically the same as Photoelectric device Example 1, and only the difference is that films are separately formed on the ITO anode according to the method of Examples 2-17 to prepare hole functional layer.

### Photoelectric Device Comparative Examples 1-3

Photoelectric device Comparative Examples 1-3 are basically the same as Photoelectric device Example 1, and only the difference is that films are separately formed on the ITO anode according to the method of Comparative Examples 1-3 to prepare hole functional layer.

### Performance Test:

The external quantum efficiency (EQE) and lifetime T95@1000 nit of the photoelectric devices in Photoelectric device Examples 1-17 and Photoelectric device Comparative Examples 1-3 were tested respectively. The result obtained are shown in Table 2.

The external quantum efficiency is an important parameter to measure the quality of electroluminescent devices, which could be measured by EQE optical testing instrument. The external quantum efficiency represents the ratio of the electron-hole logarithm injected into a quantum dot to the number of photons emitted, and the unit is %. The specific calculation formula is as follows:

$$EQE = η e η r χ \frac{{K}_{R}}{{K}_{R} + {K}_{NR}} .$$

Where ηe is the light output coupling efficiency, ηr is the ratio of the number of recombination carriers to the number of injected carriers, χ is the ratio of the number of excitons generating photons to the total number of excitons, K_{R} is the radiation process rate, and K_{NR} is the non-radiation process rate. The test was carried out at room temperature, and the air humidity was 30%-60%.

When photoelectric device is driven by constant current, the time when the brightness drops to 95% of the highest brightness is defined as T95, which indicates the measured lifetime. In order to shorten the test period, the photoelectric device lifetime test is usually carried out by accelerating the aging of the photoelectric device under high brightness, and the lifetime under high brightness is obtained by fitting the extended exponential decay brightness attenuation formula, for example, the lifetime at 1000 nit is T95@1000 nit. The specific calculation formula is as follows:

$$T {95}_{L} = T {95}_{H} \cdot {( \frac{{L}_{H}}{{L}_{L}} )}^{A} .$$

Where T95_{L} is the lifetime under low brightness, T95_{H} is the measured lifetime under high brightness, L_{H} is the acceleration of the device to the highest brightness, L_{L} is 1000 nit, and A is the acceleration factor. In this experiment, the lifetime of several groups of QLED devices under rated brightness is measured and the value of A is 1.7.

TABLE 2

| | EQE | T95@1000 nit |
|---|---|---|
| | (%) | (h) |
| Photoelectric device Example 1 | 15.3 | 123.5 |
| Photoelectric device Example 2 | 14.6 | 118.2 |
| Photoelectric device Example 3 | 16.1 | 125.8 |
| Photoelectric device Example 4 | 12.5 | 105.3 |
| Photoelectric device Example 5 | 14.1 | 105.8 |
| Photoelectric device Example 6 | 12.6 | 101.6 |
| Photoelectric device Example 7 | 11.3 | 88.6 |
| Photoelectric device Example 8 | 13.8 | 106.7 |
| Photoelectric device Example 9 | 12.1 | 90.4 |
| Photoelectric device Example 10 | 13.1 | 112.6 |
| Photoelectric device Example 11 | 11.6 | 84.5 |
| Photoelectric device Example 12 | 12.3 | 92.1 |
| Photoelectric device Example 13 | 16.8 | 142.5 |
| Photoelectric device Example 14 | 15.1 | 108.7 |
| Photoelectric device Example 15 | 16.7 | 131.8 |
| Photoelectric device Example 16 | 17.9 | 155.3 |
| Photoelectric device Example 17 | 15.3 | 120.3 |
| Photoelectric device Comparative Example 1 | 9.8 | 67.5 |
| Photoelectric device Comparative Example 2 | 10.7 | 75.3 |
| Photoelectric device Comparative Example 3 | 11.1 | 78.9 |

From Photoelectric device Examples 1-5 and Photoelectric device Comparative Examples 1-2, it could be seen that after the dopant is arranged on the hole functional layer, the luminous efficiency of the photoelectric device could be effectively improved and the lifetime of the photoelectric device could be prolonged by organic solvent vapor treatment. The influence of dopant polytrifluoromethyl conjugated compound on the performance of photoelectric devices is better than that of dopant polycyano conjugated compound. The influence of TFB as hole functional material on the performance of photoelectric devices is better than PVK. The effect of carbon disulfide vapor treatment on the performance of photoelectric devices is better than that of tetrahydrofuran vapor. Compared with the Photoelectric device Comparative Example 2, in which the composite layer of dopant and hole functional material is directly arranged, in the Photoelectric device Example 1, the organic solvent vapor treatment is adopted to make the dopant penetrate into the hole functional material, which could effectively improve the luminous efficiency of the photoelectric device and prolong the lifetime of the photoelectric device.

From Photoelectric device Examples 1, 6-11 and Photoelectric device Comparative Examples 1, it could be known that within the range provided by the present disclosure, the better the performance of photoelectric devices will be improved if the carbon disulfide vapor treatment time is moderate, the heat treatment temperature after solvent vapor treatment is moderate and the heat treatment time is moderate. The luminous efficiency and lifetime of photoelectric devices in Photoelectric device Example 1, 6-11 are higher than photoelectric device in Photoelectric device Comparative Example 1.

From Photoelectric device Example 1, 12-17, and Photoelectric device Comparative Examples 1, 3, it could be seen that the performance of the photoelectric device of the composite layer mixed with single-layer dopant and hole functional material is worse than that of the multi-layer dopant gradient doping hole functional material. The organic solvent vapor treatment in this scheme promotes the multi-layer gradient doping of dopants and the recombination between doped layers, thus promoting the transmission of holes, and its influence on the performance of photoelectric devices is better than that of Photoelectric device Comparative Example 3 in which the composite layers are directly arranged in gradient order.

Film, preparation method thereof and photoelectric device are described in detail above. The principles and embodiments of the present disclosure have been described with reference to specific embodiments, and the description of the above embodiments is merely intended to aid in the understanding of the method of the present disclosure and its core idea. At the same time, changes may be made by those skilled in the art to both the specific implementations and the scope of present disclosure in accordance with the teachings of the present disclosure. In view of the foregoing, the content of the present specification should not be construed as limiting the disclosure.

What is claimed is:

1. A film, wherein a material of the film comprises an organic p-type semiconductor material and a dopant, and the dopant is selected from one or more of a polycyano conjugated compound and a polytrifluoromethyl conjugated compound.

2. The film according to claim 1, wherein the polycyano conjugated compound is selected from one or more of formula (I), formula (II), formula (III) and formula (IV): 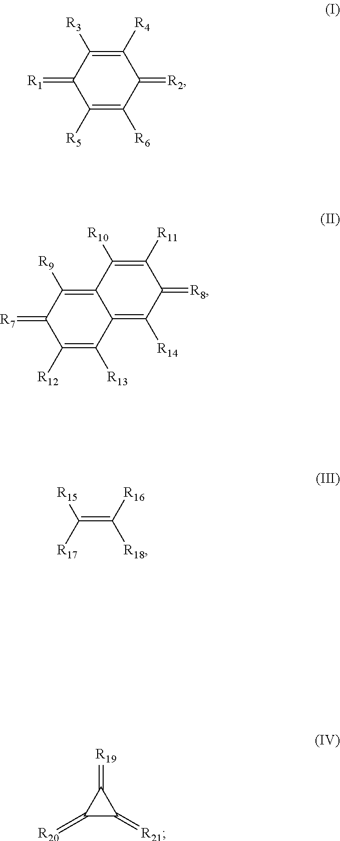
wherein, R₁, R₂, R₇, R₈, R₁₉, R₂₀, R₂₁ is each independently selected from the group consisting of oxygen or 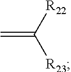
R₃, R₄, R₅, R₆, R₉, R₁₀, R₁₁, R₁₂, R₁₃, R₁₄, R₁₅, R₁₆, R₁₇, R₁₈, R₂₂, R₂₃ is each independently selected from one or more of cyano, halogen, ester, acyl, aldehyde, carboxyl, carbonyl, amido, sulfonic acid, nitro and quaternary amino groups;
when R₂₂, R₂₃ and R₃, R₄, R₅, R₆ appear, at least two of them are simultaneously selected from cyano;
when R₂₂, R₂₃ and R₉, R₁₀, R₁₁, R₁₂, R₁₃, R₁₄ appear, at least two of them are simultaneously selected from cyano;
when R₁₅, R₁₆, R₁₇, R₁₈ appear, at least two of them are simultaneously selected from cyano; and
when R₁₉, R₂₀, R₂₁ appear, at least one is selected from 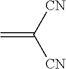
or at least two are selected from 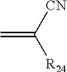
at the same time, and R₂₄ is selected from one or more of halogen group, ester group, acyl group, aldehyde group, carboxyl group, carbonyl group, amido group, sulfonic group, nitro group and quaternary amine group.

3. The film according to claim 2, wherein the 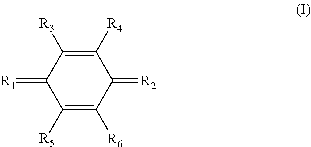
is selected from one or more of 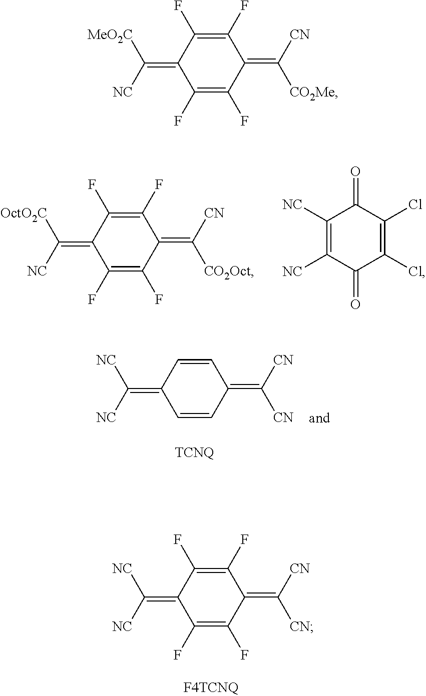
the 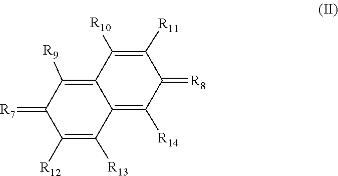
the is selected from 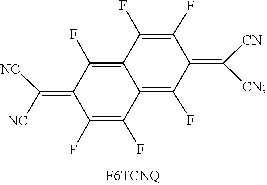 [SMILES: N#CC(C#N)=c1c(F)c(F)c2c(F)c(=C(C#N)C#N)c(F)c(F)c2c1F]
the 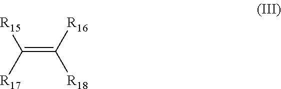
is selected from 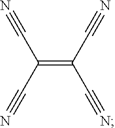
and
the 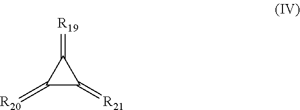
is selected from

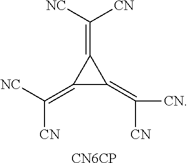 [SMILES: "CN6CP" ; N#CC(C#N)=C1C(=C(C#N)C#N)C1=C(C#N)C#N]

4. The film according to claim 1, wherein the polytrifluoromethyl conjugated compound is selected from formula (V): 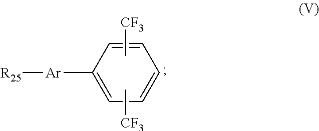
wherein, R₂₅ is selected from one or more of hydrogen group, deuterium group, halogen group, ester group, acyl group, aldehyde group, carboxyl group, carbonyl group, amido group, sulfonic acid group, nitro group, quaternary amine group and 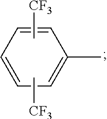
and
Ar is selected from substituted or unsubstituted aryl with 6-60 ring atoms, substituted or unsubstituted heteroaryl with 5-60 ring atoms, or their combination, and heteroatom in the heteroaryl group comprise one or more of O, P, N and S.

5. The film according to claim 4, wherein the 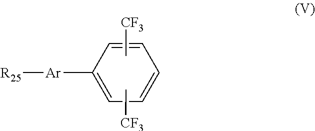
is selected from one or more of

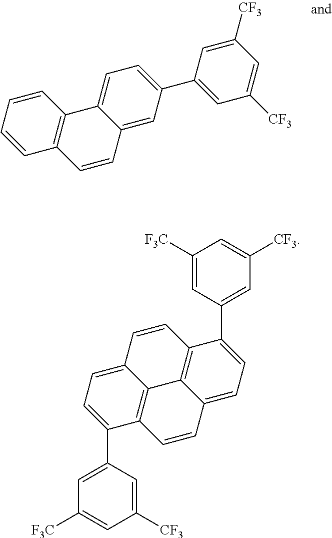 [SMILES: FC(F)(F)c1cc(-c2ccc3c(ccc4ccccc43)c2)cc(C(F)(F)F)c1 ; FC(F)(F)c1cc(-c2ccc3ccc4c(-c5cc(C(F)(F)F)cc(C(F)(F)F)c5)ccc5ccc2c3c54)cc(C(F)(F)F)c1]

6. The film according to claim 1, wherein the film comprises at least two film layers, and a mass fraction of the dopant in each film layer tends to increase or decrease in the same direction.

7. The film according to claim 6, wherein the organic p-type semiconductor material comprises a first organic p-type semiconductor material, and the film comprises a first film layer and a second film layer which are stacked, wherein a material of the first film layer comprises the first organic p-type semiconductor material, and a material of the second film layer comprises the first organic p-type semiconductor material and the dopant.

8. The film according to claim 6, wherein the organic p-type semiconductor material comprises a first organic p-type semiconductor material and a second organic p-type semiconductor material, and the film comprises a first film layer, a second film layer . . . a 2M film layer and a 2M+1 film layer which are stacked; and a material of the first film layer comprises the first organic p-type semiconductor material, and the second film layer to the 2M+1 film layer all comprises the second organic p-type semiconductor material and the dopant, and in any two adjacent films from the second film layer to the 2M+1 film layer, a mass fraction of the dopant in the latter film layer is greater than that in the previous film layer.

9. The film according to claim 8, wherein the first organic p-type semiconductor material is the same as or different from the second organic p-type semiconductor material; the second organic p-type semiconductor materials in different film layers are the same or different: the dopants in different film layers are the same or different; and
the first organic p-type semiconductor material and the second organic p-type semiconductor material in different film layers is independently selected from one or more of 4,4′-N,N′-dicarbazolyl-biphenyl, N,N′-diphenyl-N,N′-bis (1-naphthyl)-1,1′-biphenyl)-4,4′-diamine, N,N′-bis (3-methylphenyl)-N,N′-bis (phenyl)-spiro, N,N′-bis (4-(N,N′-diphenyl-amino) phenyl)-N,N′-diphenylbenzidine, 4,4′,4′-tris (N-carbazolyl)-triphenylamine, 4,4′,4′-tris (carbazole-9-yl)triphenylamine, trichloroisocyanuric acid, terbium-doped phosphate-based green luminescent material, 2,3,6,7,10,11-hexacyano-1,4,5,8,9,12-hexaazaphenanthrene, 4,4′,4′-tris (N-3-methylphenyl-N-phenylamino) triphenylamine, poly [(9,9′-dioctyl fluorene-2,7-diyl)-co-(4, 4′-(N-(4-sec-butylphenyl) diphenylamine))], poly (4-butylphenyl-diphenylamine), poly [bis(4-phenyl) (4-butylphenyl) amine], polyaniline, polypyrrole, poly (p) phenylene vinylene, poly (phenylene vinylene), poly [2-methoxy-5-(2-ethylhexyloxy)-1,4-phenylene vinylene], poly [2-methoxy-5-(3′,7′-dimethyl octyloxy)-1,4-phenylene vinylene], copper phthalocyanine, aromatic tertiary amine, 4,4′-bis (p-carbazolyl)-1,1′-biphenyl compound, N,N,N′,N′-tetraarylbenzidine, poly(9,9-dioctylfluorene-alt-N-(4-sec-butylphenyl)-diphenylamine), PEDOT, PEDOT:PSS and its derivatives, PEDOT:PSS derivatives doped with s-MoO₃, poly (N-vinylcarbazole) and its derivatives, polymethacrylate and its derivatives, poly (9,9-octylfluorene) and its derivatives, poly (spirofluorene) and its derivatives, N,N′-bis (naphthalene-1-yl)-N,N′-diphenylbenzidine, spiro NPB, microcrystalline cellulose and tetracyanoquinone dimethylmethane.

10. A preparation method of a film, comprising:
providing a prefabricated film layer, and a material of the prefabricated film layer comprises a first organic p-type semiconductor material; and
providing a first material, setting the first material on the prefabricated film layer to form a first doped layer, and treating with organic solvent vapor to obtain the film;
wherein the first material comprises a dopant, and the dopant is selected from one or more of a polycyano conjugated compound and a polytrifluoromethyl conjugated compound.

11. The preparation method according to claim 10, wherein the polycyano conjugated compound is selected from one or more of formula (I), formula (II), formula (III) and formula (IV): 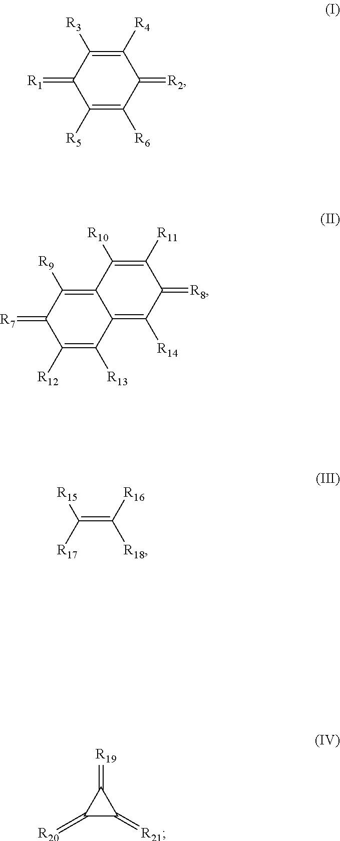
wherein, R₁, R₂, R₇, R₈, R₁₉, R₂₀, R₂₁ is each independently selected from the group consisting of oxygen or 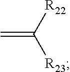
R₃, R₄, Rs, R₆, R₉, R₁₀, R₁₁, R₁₂, R₁₃, R₁₄, R₁₅, R₁₆, R₁₇, R₁₈, R₂₂, R₂₃ is each independently selected from one or more of cyano, halogen, ester, acyl, aldehyde, carboxyl, carbonyl, amido, sulfonic acid, nitro and quaternary amino groups;
when R₂₂, R₂₃ and R₃, R₄, R₅, R₆ appear, at least two of them are simultaneously selected from cyano;
when R₂₂, R₂₃ and R₉, R₁₀, R₁₁, R₁₂, R₁₃, R₁₄ appear, at least two of them are simultaneously selected from cyano;
when R₁₅, R₁₆, R₁₇, R₁₈ appear, at least two of them are simultaneously selected from cyano; and
when R₁₉, R₂₀, R₂₁ appear, at least one is selected from 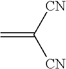
or at least two are selected from 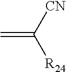
at the same time, and R₂₄ is selected from one or more of halogen group, ester group, acyl group, aldehyde group, carboxyl group, carbonyl group, amido group, sulfonic group, nitro group and quaternary amine group.

12. The preparation method according to claim 10, wherein the polytrifluoromethyl conjugated compound is selected from formula (V): 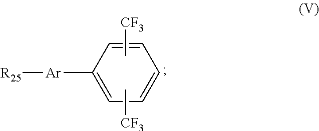
wherein, R₂₅ is selected from one or more of hydrogen group, deuterium group, halogen group, ester group, acyl group, aldehyde group, carboxyl group, carbonyl group, amido group, sulfonic acid group, nitro group, quaternary amine group and 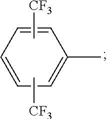
and
Ar is selected from substituted or unsubstituted aryl with 6-60 ring atoms, substituted or unsubstituted heteroaryl with 5-60 ring atoms, or their combination, and heteroatom in the heteroaryl group comprise one or more of O, P, N and S.

13. The preparation method according to claim 10, wherein the organic solvent vapor is selected from one or more of carbon disulfide, chloroform, dichloromethane, ethyl acetate and tetrahydrofuran;
a treatment time of the organic solvent vapor ranges between 1 min-30 min;
the treating with organic solvent vapor comprises: introducing the organic solvent vapor, or placing in the organic solvent vapor atmosphere; and
after the treating with the organic solvent vapor, further comprises thermal annealing; a temperature of the thermal annealing ranges between 100° C.-250° C., and a time of the thermal annealing ranges between 10 min-60 min.

14. The preparation method according to claim 10, wherein the first material further comprises a second organic p-type semiconductor material, and after the treating with the organic solvent vapor, a first film layer, a second film layer and a third film layer are obtained:
a material of the first film layer comprises the first organic p-type semiconductor material, a material of the second film layer comprises the first organic p-type semiconductor material, the second organic p-type semiconductor material and the dopant, and a material of the third film layer comprises the second organic p-type semiconductor material and the dopant, and a mass fraction of the dopant in the third film layer is greater than that in the second film layer.

15. The preparation method according to claim 14, wherein after obtaining the third film layer, further comprises forming at least one film layer on the third film layer; wherein, each of the film layer comprises the second organic p-type semiconductor material and the dopant, and in any two adjacent film layers in the direction from the second film layer to the third film layer, a mass fraction of the dopant in the latter film layer is greater than that in the previous film layer.

16. The preparation method according to claim 15, wherein a method for forming the film layer comprises: providing an M material, wherein the M material comprises a second organic p-type semiconductor material and a dopant, and a mass fraction of the dopant in the M material is greater than that in the previous film layer; setting the M material on the previous film layer to form an M doped layer, and an organic solvent vapor treatment is adopted to obtain a 2M film layer and a (2M+1) film layer, wherein M is an integer greater than or equal to 2.

17. The preparation method according to claim 15, wherein the second organic p-type semiconductor materials in different film layers are the same or different: the dopants in different film layers are the same or different: the organic solvent vapor used to treat different doped layers is the same or different; and the treatment time of the organic solvent vapor on different doped layers is the same or different.

18. A photoelectric device, comprising:
an anode;
an active layer, located on the anode;
a cathode, located on the active layer; and
a hole functional layer, between the anode and the active layer, and a material of the film comprises an organic p-type semiconductor material and a dopant, and the dopant is selected from one or more of a polycyano conjugated compound and a polytrifluoromethyl conjugated compound.

19. The photoelectric device according to claim 18, wherein the organic p-type semiconductor material comprises a first organic p-type semiconductor material, and the film comprises a first film layer and a second film layer which are stacked, wherein the first film layer is arranged between the anode and the second film layer, and a material of the first film layer comprises the first organic p-type semiconductor material, and a material of the second film layer comprises the first organic p-type semiconductor material and the dopant; or
the organic p-type semiconductor material comprises a first organic p-type semiconductor material and a second organic p-type semiconductor material, and the film comprises a first film layer, a second film layer . . . a 2M film layer and a 2M+1 film layer which are stacked along the direction from the anode to the active layer; a material of the first film layer comprises the first organic p-type semiconductor material, and the second film layer to the 2M+1 film layer all comprises the second organic p-type semiconductor material and the dopant, and in any two adjacent film layers from the second film layer to the 2M+1 film layer, a mass fraction of the dopant in each film layer increases in turn along the direction from the anode to the active layer.

20. The photoelectric device according to claim 18, wherein a material of the anode and the cathode is each independently selected from one or more of metal, carbon material and metal oxide, and the metal is selected from one or more of Al, Ag, Cu, Mo, Au, Ba, Ca, Yb and Mg, and the carbon material is selected from one or more of graphite, carbon nanotubes, graphene and carbon fiber, and the metal oxide is selected from one or more of metal oxide electrode or composite electrode with metal sandwiched between doped or undoped transparent metal oxide, and a material of the metal oxide electrode is selected from one or more of ITO, FTO, ATO, AZO, GZO, IZO, MZO, MoO; and AMO, and the composite electrode is selected from one or more of AZO/Ag/AZO, AZO/Ag/AZO, ITO/Ag/ITO, ITO/Al/ITO, ZnO/Ag/ZnO, ZnO/Al/ZnO, ZnS/Ag/ZnS, ZnS/Al/ZnS, TiO₂/Ag/TiO₂ and TiO₂/Al/TiO₂;
the active layer comprises luminescent layer, a material of the luminescent layer is selected from one or more of organic luminescent material and quantum dot luminescent material; and a material of the organic luminescent material is selected from one or more of CBP:Ir(mppy)3, TCTX:Ir(mmpy), diarylanthracene derivatives, stilbene aromatic derivatives, pyrene derivatives, fluorene derivatives, TBPc fluorescent materials, TTPX fluorescent materials, TBRb fluorescent materials, DBP fluorescent materials, delayed fluorescent materials, TTA materials, TADF materials, polymers containing B—N covalent bonds, HLCT materials and Exciplex luminescent materials, and the quantum dot luminescent material is selected from one or more of single-structure quantum dot, core-shell quantum dot and perovskite-type semiconductor material; a material of the single-structure quantum dot, a core material of the core-shell quantum dot and a shell material of the core-shell quantum dot could be respectively selected from but not limited to one or more of second II-VI compound, second IV-VI compound, second III-V compound and I-III-VI compound; and a shell layer of the core-shell structure quantum dot comprises one or more layers; the second II-VI compound is selected from one or more of CdS, CdSe, CdTe, ZnS, ZnSe, ZnTe, HgS, HgSe, HgTe, CdSeS, CdSeTe, CdSTe, ZnSeS, ZnSeTe, ZnSTe, HgSeS, HgSeTe, HgSTe, CdZnS, CdZnSe, CdZnTe, CdHgS, CdHgSe, CdHgTe, HgZnS, HgZnSe, HgZnTe, CdZnSeS, CdZnSeTe, CdZnSTe, CdHgSeS, CdHgSeTe, CdHgSTe, HgZnSeS, HgZnSeTe and HgZnSTe; the second IV-VI compound is selected from one or more of SnS, SnSe, SnTe, PbS, PbSe, PbTe, SnSeS, SnSeTe, SnSTe, PbSeS, PbSeTe, PbSTe, SnPbS, SnPbSe, SnPbTe, SnPbSSe, SnPbSeTe and SnPbSTe; the second III-V compound is selected from one or more of GaN, GaP, GaAs, GaSb, AlN, AlP, AlAs, AlSb, InN, InP, InAs, InSb, GaNP, GaNAs, GaNSb, GaPAs, GaPSb, AlNP, AlNAs, AlNSb, AlPAs, AlPSb, InNP, InNAs, InNSb, InPAs, InPSb, GaAlNP, GaAlNAs, GaAlNSb, GaAlPAs, GaAlPSb, GaInNP, GaInNAs, GaInNSb, GaInPAs, GaInPSb, InAlNP, InAlNAs, InAlNSb, InAlPAs and InAlPSb; the I-III-VI compound is selected from one or more of CuInS₂, CuInSe₂ and AgInS₂; and the core-shell quantum dot is selected from one or more of CdSe/CdSeS/CdS, InP/ZnSeS/ZnS, CdZnSe/ZnSe/ZnS, CdSe/ZnS, CdSe/ZnSe, ZnSe/ZnS, ZnSe/ZnS, ZnSe/ZnS, and ZnSe/ZnSe/ZnSe; and the perovskite semiconductor material is selected from one of doped or undoped inorganic perovskite semiconductor or organic-inorganic hybrid perovskite semiconductor; a general structural formula of the inorganic perovskite semiconductor is AMX₃, wherein A is Cs⁺, and X is divalent metal cation, which is selected from one or more of Pb²⁺, Sn²⁺, Cu²⁺, Ni²⁺, Cd²⁺, Cr²⁺, Mn²⁺, Co²⁺, Fe²⁺, Ge²⁺, Yb²⁺ and Eu²⁺, and X is a halogen anion selected from one or more of Cl⁻, Br⁻ and I⁻; the general structural formula of the organic-inorganic hybrid perovskite semiconductor is BMX₃, wherein B is an organic amine cation selected from CH₃(CH₂)ₙ₋₂NH₃⁺ or [NH₃(CH₂)ₙNH³]²⁺, wherein n≥2, and M is a divalent metal cation selected from Pb²⁺, Sn²⁺, Cu²⁺, Ni²⁺, Cd²⁺ and Cr³⁺, and X is a halogen anion selected from one or more of Cl⁻, Br⁻ and I⁻; and
the photoelectric device further comprises an electronic functional layer disposed between the active layer and the cathode, a material of the electronic functional layer is selected from one or more of first doped metal oxide particle, first undoped metal oxide particle, IIB-VIA semiconductor material, IIIA-VA semiconductor material and IB-IIIA-VIA semiconductor material, and a material of the first undoped metal oxide particle is selected from one or more of ZnO, TiO₂, SnO₂, ZrO₂ and Ta₂O₅, and a metal oxide in the first doped metal oxide particle is selected from one or more of ZnO, TiO₂, SnO₂, ZrO₂, Ta₂O₅ and Al₂O₃, and a doping element in the first doped metal oxide particle is selected from one or more of Al, Mg, Li, Mn, Y, La, Cu, Ni, Zr, Ce, In and Ga, and the IIB-VIA semiconductor material is selected from one or more of ZnS, ZnSe and CdS, and the IIIA-VA semiconductor material is selected from one or more of InP and GaP, and the IB-IIIA-VIA family semiconductor material is selected from one or more of CuInS and CuGaS.
